(19) United States
(12) Patent Application Publication
(10) Pub. No.: US 2025/0015141 A1
(43) Pub. Date: Jan. 9, 2025

(54) SEMICONDUCTOR DEVICE AND FORMATION METHOD THEREOF

(71) Applicants: TAIWAN SEMICONDUCTOR MANUFACTURING COMPANY, LTD., Hsinchu (TW); NATIONAL TAIWAN UNIVERSITY, Taipei (TW)

(72) Inventors: Jian-Zhi HUANG, Changhua County (TW); Yu-Tung LIN, Taoyuan City (TW); En-Cheng CHANG, Pingtung County (TW); Ting-Ying CHIU, Taipei City (TW); I-Chih NI, New Taipei City (TW); Chih-I WU, Taipei City (TW)

(73) Assignees: TAIWAN SEMICONDUCTOR MANUFACTURING COMPANY, LTD., Hsinchu (TW); NATIONAL TAIWAN UNIVERSITY, Taipei (TW)

(21) Appl. No.: 18/348,646

(22) Filed: Jul. 7, 2023

(51) Int. Cl. H01L 29/18; H01L 29/16; H01L 29/417; H01L 29/43

(52) U.S. Cl. CPC H01L 29/18; H01L 29/1606; H01L 29/41725; H01L 29/43

(57) ABSTRACT

A semiconductor device includes a substrate, a first dielectric layer, a channel layer and source/drain electrodes. The first dielectric layer is over the substrate. The channel layer is over the first dielectric layer. Source/drain electrodes are over the channel layer. The source/drain electrodes comprise a 2D semimetal material. The channel layer comprises a 2D semiconductor material interfacing the 2D semimetal material of the source/drain electrodes.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a cross-sectional view of a semiconductor device in various stages of fabrication in accordance with some embodiments of the present disclosure.

FIG. 1B is an enlarged view of a region R1 in FIG. 1A.

FIGS. 2-10A are cross-sectional views of a semiconductor device in various stages of fabrication in accordance with some embodiments of the present disclosure.

FIG. 10B illustrates a schematic view of a mono-layer of an example TMD in accordance with some example embodiments.

FIGS. 11-13 are cross-sectional views of a semiconductor device in various stages of fabrication in accordance with some embodiments of the present disclosure.

FIG. 14 is a band diagram illustrating an energy barrier between the first 2D material layer and the second 2D material layer of the semiconductor device in FIG. 13.

FIG. 15A is a cross-sectional view of a semiconductor device in various stages of fabrication in accordance with some other embodiments of the present disclosure.

FIG. 15B is a deposition system in accordance with some embodiments of the present disclosure.

FIG. 16A is a cross-sectional view of a semiconductor device in various stages of fabrication in accordance with some other embodiments of the present disclosure.

FIG. 16B is an enlarged view of a region in FIG. 16A.

FIGS. 17-20 are cross-sectional views of a semiconductor device in various stages of fabrication in accordance with some other embodiments of the present disclosure.

FIG. 21 is a band diagram illustrating an energy barrier between the first 2D material layer and the second 2D material layer of the semiconductor device in FIG. 20.

FIG. 22 is a diagram illustrating a current versus voltage (I-V) curve of the semiconductor device of FIG. 13 according to one embodiment.

FIG. 23 is a diagram illustrating a current versus voltage (I-V) curve of the semiconductor device of FIG. 20 according to one embodiment.

FIG. 24 is a graph of transfer curves for the semiconductor device of FIG. 13 in accordance with some embodiments.

FIG. 25 is a graph of an output curve for the semiconductor device of FIG. 13 in accordance with some embodiments in dependency on the gate voltage.

FIGS. 26 and 27 are cross-sectional views of a semiconductor device in various stages of fabrication in accordance with some embodiments of the present disclosure.

FIGS. 28 and 29 are cross-sectional views of a semiconductor device in various stages of fabrication in accordance with some embodiments of the present disclosure.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. As used herein, “around,” “about,” “approximately,” or “substantially” shall generally mean within 20 percent, or within 10 percent, or within 5 percent of a given value or range. Numerical quantities given herein are approximate, meaning that the term “around,” “about,” “approximately,” or “substantially” can be inferred if not expressly stated.

Work function materials provide a desired work function for transistors to enhance device performance including an improved threshold voltage. The use of different metals to change the work function is required. However, metals with high work function formed by an electron gun (E-gun) evaporation process tend to cause damage to an integrated circuit device.

In a recent development of a field effect transistor (FET), a channel region of the FET may be formed in a two dimensional (2D) material layer, which may provide the FET with improved performance (e.g. relative to FETs that are devoid of a 2D material layer). However, due to Fermi Level Pinning (FLP) in the 2D material at an interface between a metal contact and the 2D material, properties of the transistor cannot be easily changed.

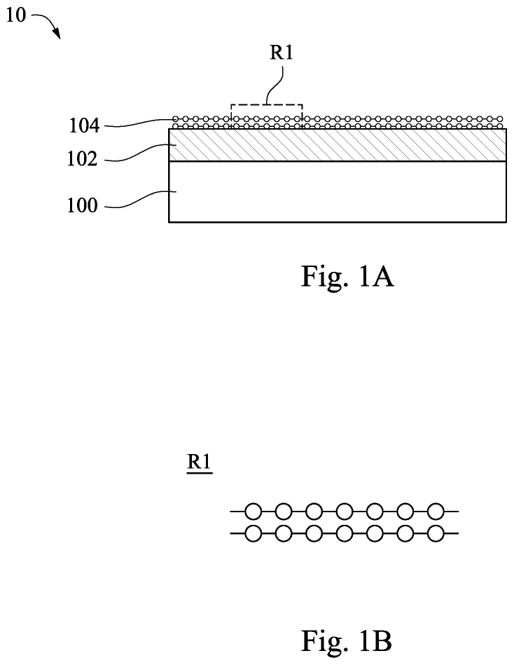

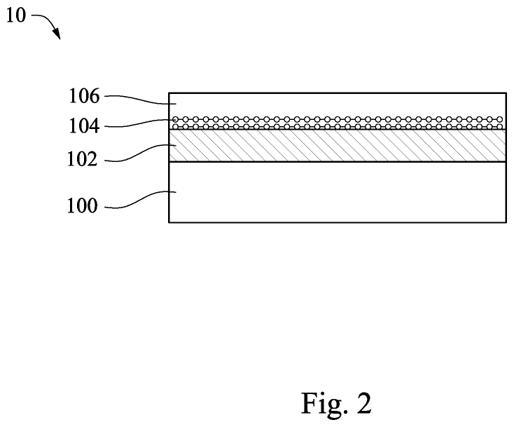

FIGS. 1A, 2-10A and 11-13 are cross-sectional views of a semiconductor device 10 in various stages of fabrication in accordance with some embodiments of the present disclosure. Reference is made to FIG. 1A. A dielectric layer 102 is formed on a first substrate 100. In certain embodiments, the dielectric layer 102 is an oxide layer, such as a silicon oxide layer. In some examples where the dielectric layer 102 is an oxide layer, the dielectric layer 102 may be formed by thermal oxidation, chemical vapor deposition (CVD), including low pressure CVD (LPCVD) and plasma enhanced CVD (PECVD), physical vapor deposition (PVD), atomic layer deposition (ALD), or other suitable process. In some embodiments, the dielectric layer 102 may be made of a nitride layer, such as SiNₓ or a silicon nitride-based material (e.g., SiON, SiCN or SiOCN) formed using CVD. PVD. ALD, or other suitable process. In some embodiments, the dielectric layer 102 has a thickness in a range from about 5 nm to about 200 nm.

A first 2D material layer 104 is disposed over the dielectric layer 102. In certain embodiments, the first 2D material layer includes one or more sub-layers, for example, made of graphene. In some embodiments, the first 2D material layer 104 is formed on another substrate and then transferred and subsequently reattached to the dielectric layer 102. For example, a first 2D material layer 104 is formed on a carrier substrate by chemical vapor deposition (CVD), sputtering or atomic layer deposition (ALD) in some embodiments. A polymer film, such as poly(methyl methacrylate) (PMMA), is subsequently formed on the first 2D material layer 104. After forming the polymer film, the sample is heated, such as by placing the sample on a hot plate. Subsequent to heating, a corner of the first 2D material layer 104 is peeled off the carrier substrate, such as by using a tweezers, and the sample is submerged in a solution to facilitate the separation of the first 2D material layer 104 from the carrier substrate. The first 2D material layer 104 and polymer film are transferred to the dielectric layer 102. The polymer film is then removed from the first 2D material layer 104 using a suitable solvent.

As an example, the first 2D material layer 104 may include one or more layers of graphene. In other words, the first 2D material layer 104 can be referred to as a graphene-containing layer in some embodiments. In such an example, the first 2D material layer 104 may be a single-layer graphene film (e.g., a one molecule thick graphene layer) or a bi-layer graphene film (e.g., a two molecule thick graphene layer). In another example, the first 2D material layer 104 may include a three or more layers of graphene films. In certain embodiments, the first 2D material layer 104 may be a multilayer graphene structure with a thickness in a range from about 0.37 nm to about 50 nm. FIG. 1B is an enlarged view of a region R1 in FIG. 1A. In FIG. 1B, the two-monolayer thick graphene includes carbon atoms 105.

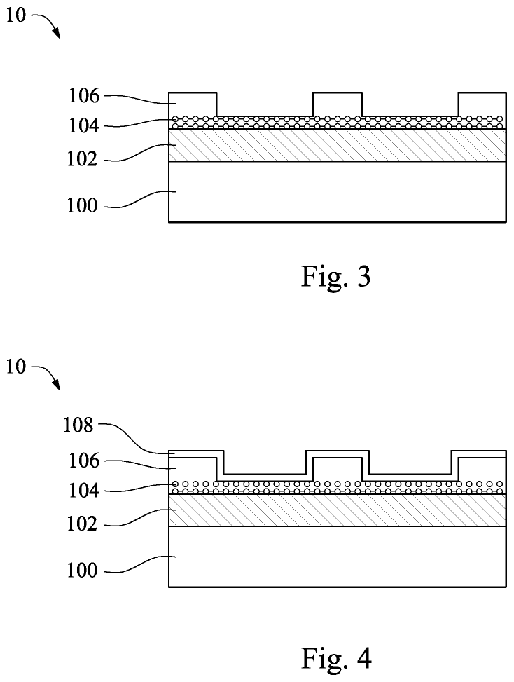

Reference is made to FIG. 2. A photoresist layer 106 is formed on the first 2D material layer 104. The photoresist layer 106 may be a photosensitive material deposited using spin-on coating, CVD, plasma enhanced CVD, ALD, or the like. In some embodiments, the photoresist layer 106 has a thickness in a range from about 50 nm to about 1000 nm.

Reference is made to FIG. 3. The photoresist layer 106 may be patterned to expose regions of the first 2D material layer 104 using, for example, a lithography process including a lithographic exposure step followed by a lithographic development step. Reference is made to FIG. 4. A hard mask layer 108 is formed on the patterned photoresist layer 106 and the first 2D material layer 104. In some embodiments, the hard mask layer 108 may be a conductive layer or a metal layer, such as chromium (Cr) or the like. In certain embodiments, the hard mask layer 108 may be formed by a suitable deposition process. The deposition process, for example, includes physical vapor deposition (PVD) such as sputtering and evaporation, plating, CVD such as plasma enhanced CVD (PECVD), atmospheric pressure CVD (APCVD), low pressure CVD (LPCVD), high density plasma CVD (HDPCVD), atomic layer CVD (ALCVD), or other suitable deposition process. The hard mask layer 108 may be conformally deposited on the patterned photoresist layer 106. In some embodiments, the hard mask layer 108 has a thickness in a range from about 5 nm to about 15 nm.

Reference is made to FIG. 5. The patterned photoresist layer 106 is removed by a photoresist removal process, such as a stripping or an ashing process. The hard mask layer 108 over the patterned photoresist layer 106 is removed, and the hard mask layer 108 remains over the first 2D material layer 104. Stated differently, the patterned photoresist layer 106 is “lift-off.” The lift-off process removes the remaining photoresist and portions of the hard mask layer 108 over the patterned photoresist layer 106, leaving behind only portions of the hard mask layer 108 in the regions where the photoresist was removed earlier (i.e., at the step as illustrated in FIG. 3).

Reference is made to FIG. 6. The first 2D material layer 104 is etched by using the hard mask layer 108 as an etch mask, exposing the dielectric layer 102. In some embodiments, a dry etching process S100 such as a plasma etching process is performed to etch the first 2D material layer 104. Various types of plasma etch processes include plasma etching, reactive ion (RI) etching and reactive ion beam etching. In each of these plasma processes, a gas is first introduced into a reaction chamber and then plasma is generated from the gas. In certain embodiments, the plasma etch processes is carried out by introducing an oxygen gas into the reaction chamber and then plasma is generated from the oxygen gas for a time from about 30 seconds to about 5 minutes.

Reference is made to FIG. 7. The hard mask layer 108 is then removed, exposing a top surface of the first 2D material layer 104. In some embodiments, the hard mask layer 108 is removed by an etching process such as a dry etching, a wet etching or a combination thereof. For example, the hard mask layer 108 is removed by a wet etching process using an etchant selective to the hard mask layer 108. In certain embodiments, the hard mask layer 108 is removed by a wet etching process using an etching solution selective to Cr.

Reference is made to FIG. 8. An organic film 110, such as a polymer film, is subsequently formed on the first 2D material layer 104 such as using spin coating. For example, the organic film 110 may include poly(methyl methacrylate) (PMMA). In certain embodiments, the organic film 110 has a thickness is a range from about 50 nm to about 200 nm.

A substrate removing operation is then performed to the structure in FIG. 8. FIG. 9 depicts the semiconductor device 10 after the substrate removing operation removes the first substrate 100 and the dielectric layer 102. As a result of the substrate removing operation, the organic film 110 is peeled from the dielectric layer 102. Due to strong adhesion between the organic film 110 and the first 2D material layer 104, the first 2D material layer 104 is also peeled off from the dielectric layer 102 together with the organic film 110. In some embodiments of the substrate removing operation, the structure of FIG. 8 is immersed in water 112 (i.e., deionized water) such that the first substrate 100 and the dielectric layer 102 are detached from the organic film 110. Ultrasonic vibrations may be applied to the water 112 to promote the detachment of the organic film 110 and the first 2D material layer 104. In some embodiments, the water 112 is contained in a container 114 made of, for example, glass or other suitable material. Upon detachment is completed, the organic film 110 and the first 2D material layer 104 may float on the water 112, as shown in FIG. 9, and the dielectric layer 102 and the first substrate 100 may be still in the water 112.

In other embodiments, the organic film 110 is mechanically peeled off from the first substrate 100 together with the first 2D material layer 104. In other embodiments, the first substrate 100 is wet etched, thereby releasing the organic film 110 with the first 2D material layer 104. When the first substrate 100 is thick, a grinding operation is firstly performed to remove a bulk portion of the first substrate 100 from a rear side of the first substrate 100, and then a wet etching operation is performed to remove a remaining layer of the first substrate 100.

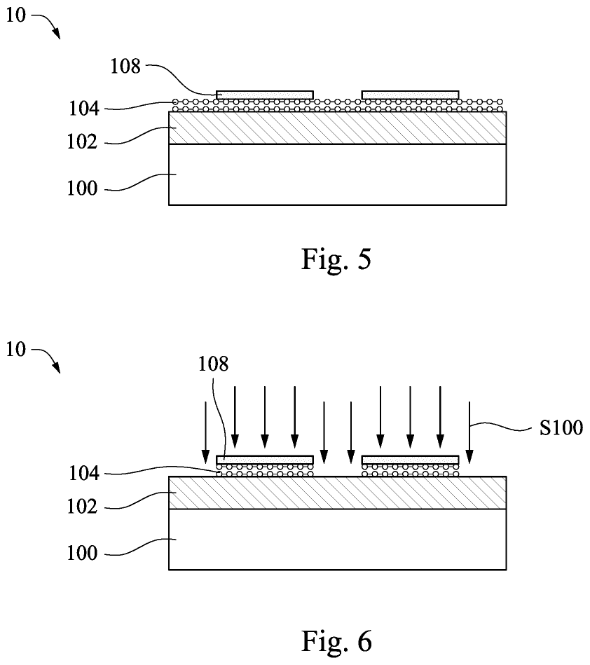

Reference is made to FIG. 10A. A dielectric layer 118 is formed on a second substrate 116. In some embodiments, the second substrate 116 and the dielectric layer 118 are similar to the first substrate 100 and the dielectric layer 102 in terms of composition, respectively. In some examples where the dielectric layer 118 is an oxide layer, the dielectric layer 118 may be formed by thermal oxidation, CVD, including low pressure CVD (LPCVD) and plasma enhanced CVD (PECVD), PVD, ALD, or other suitable process. A second 2D material layer 120 is formed over the dielectric layer 118. In certain embodiments, the second 2D material layer 120 is a 2D semiconductor layer including transition metal dichalcogenide (TMD or TMDC). In some other embodiments, the second 2D material layer 120 includes carbon nanotube (CNT), graphene, the like, or a combination thereof.

Formation of the second 2D material layer 120 may include suitable processes. In some embodiments, the second 2D material layer 120 includes a transition metal dichacogenide (TMD or TMDC) monolayer material. In some embodiments, a TMD monolayer includes one layer of transition metal atoms sandwiched between two layers of chalcogen atoms. For example, the second 2D material layer 120 is a MX₂ layer in which M is the transition metal atom such as Mo, W or the like, and X is chalcogen atom. FIG. 10B illustrates a schematic view of a mono-layer 204 of an example TMD in accordance with some example embodiments. In FIG. 10B, the one-molecule thick TMD material layer includes transition metal atoms 204M and chalcogen atoms 204X. The transition metal atoms 204M may form a layer in a middle region of the one-molecule thick TMD material layer, and the chalcogen atoms 204X may form a first layer over the layer of transition metal atoms 204M, and a second layer underlying the layer of transition metal atoms 204M. The transition metal atoms 204M may be W atoms or Mo atoms, while the chalcogen atoms 204X may be S atoms, Se atoms, or Te atoms. In the example of FIG. 10B, each of the transition metal atoms 204M is bonded (e.g. by covalent bonds) to six chalcogen atoms 204X, and each of the chalcogen atoms 204X is bonded (e.g. by covalent bonds) to three transition metal atoms 204M. Throughout the description, the illustrated cross-bonded layers including one layer of transition metal atoms 204M and two layers of chalcogen atoms 204X in combination are referred to as a mono-layer 204 of TMD.

In some embodiment where the second 2D material layer 120 includes TMD monolayers, the TMD monolayers include molybdenum disulfide (MoS₂), tungsten disulfide (WS₂), tungsten diselenide (WSe₂), or the like. In some embodiments, MoS₂ and WS₂ may be formed on the dielectric layer 118, using suitable approaches. For example, MoS₂ and WS₂ may be formed by micromechanical exfoliation and coupled over the dielectric layer 118, or by sulfurization of a pre-deposited molybdenum (Mo) film or tungsten (W) film over the dielectric layer 118. In alternative embodiments, WSe₂ may be formed by micromechanical exfoliation and coupled over the dielectric layer 118, or by selenization of a pre-deposited tungsten (W) film over the dielectric layer 118 using thermally cracked Se molecules.

In some other embodiments where MoS₂ is formed by micromechanical exfoliation, the second 2D material layer 120 is formed on another substrate and then transferred to the dielectric layer 118. For example, a 2D material film is formed on a carrier substrate by CVD, sputtering or ALD in some embodiments. A polymer film, such as poly(methyl methacrylate) (PMMA), is subsequently formed on the 2D material film. After forming the polymer film, the sample is heated, such as by placing the sample on a hot plate. Subsequent to heating, a corner of the 2D material film is peeled off the carrier substrate, such as by using a tweezers, and the sample is submerged in a solution to facilitate the separation of the 2D material film from the carrier substrate. The 2D material film and the polymer film are transferred to the dielectric layer 118. The polymer film is then removed from the 2D material film using a suitable solvent.

In some embodiments where MoS₂ is formed by sulfurizing a pre-deposited molybdenum (Mo) film over the dielectric layer 118, a Mo film may be deposited over the dielectric layer 118, by suitable process, such as using RF sputtering with a molybdenum target to form the Mo film on the dielectric layer 118. After the Mo film is deposited, the dielectric layer 118 over the second substrate 116 as well as the Mo film are moved out of the sputtering chamber and exposed to air. As a result, the Mo film will be oxidized and form Mo oxides. Then, the sample is placed in the center of a hot furnace for sulfurization. During the sulfurization procedure, Ar gas is used as a carrier gas with the S powder placed on the upstream of the gas flow. The S powder is heated in the gas flow stream to its evaporation temperature. During the high-temperature growth procedure, the Mo oxide segregation and the sulfurization reaction will take place simultaneously. If the background sulfur is sufficient, the sulfurization reaction will be the dominant mechanism. Most of the surface Mo oxides will be transformed into MoS₂ in a short time. As a result, a uniform planar MoS₂ film will be obtained on the dielectric layer 118 after the sulfurization procedure. With this process, the second 2D material layer 120 can be uniformly formed on a large-area of the dielectric layer 118.

In some embodiments, forming of the second 2D material layer 120 also includes treating the second 2D material layer 120 to obtain expected electronic properties of the second 2D material layer 120. The treating processes include thinning (namely, reducing the thickness of the second 2D material layer 120), doping, or straining, to make the second 2D material layer 120 exhibit certain semiconductor properties, e.g., including direct bandgap. The thinning of the second 2D material layer 120 may be achieved through various suitable processes, and all are included in the present disclosure. For example, plasma based dry etching, e.g., reaction-ion etching (RIE), may be used to reduce the number of monolayers of the second 2D material layer 120. In the description hereinafter, the second 2D material layer 120 may include semiconductor properties (interchangeably referred to as semiconductive 2D material layer in this context).

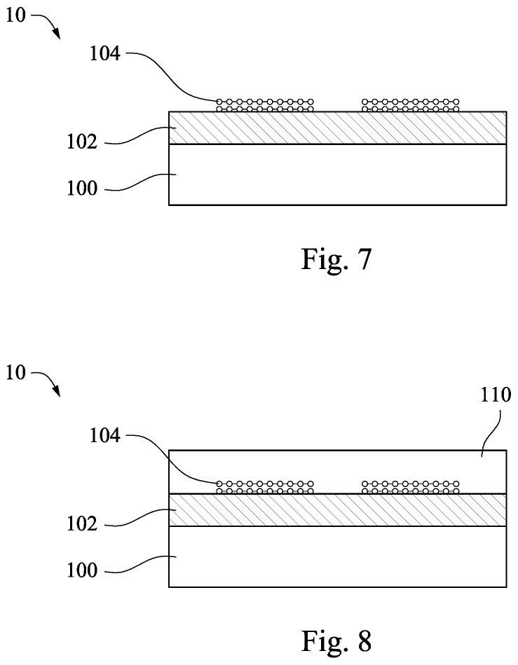

Reference is made to FIG. 11. The structure of FIG. 10A is put in the water 112 contained in the container 114 of FIG. 9, as shown by an arrow 122. In some embodiments, the second substrate 116 sinks to a bottom of the water 112. Afterwards, the water 112 is removed. As a result of removal of the water, the floated organic film 110 and the first 2D material layer 104 then naturally fall on the second 2D material layer 120, as illustrated in FIG. 12.

The organic film 110 is then removed from the first 2D material layer 104 using a suitable solvent, for example, acetone or the like. The resulting structure is shown in FIG. 13. The semiconductor device 10 constructs a bottom gate field effect transistor (FET). For example, the second substrate 116 may be doped with n-type or p-ype dopants to act as a bottom electrode, such as a bottom gate. The first 2D material layer 104 is a semimetal material and acts as source/drain electrodes. Semimetal materials are a subset of materials that fall between metals and semiconductors. The semimetal material has properties of both metals and semiconductors but not considered fully as either. For example, Semimetals (e.g., graphene) can exhibit zero bandgap like metals but may also have certain properties similar to semiconductors, such as carrier concentrations that can be modulated by external bias. The first 2D material layer 104 has separated portions spaced apart along a lateral dimension. In some embodiments, the first 2D material layer 104 is a multilayer structure made of graphene and has a thickness in a range from about 0.37 nm to about 50 nm. The second 2D material layer 120 acts as a channel layer. In some embodiments, the second 2D material layer 120 includes TMD and has a thickness in a range from about 0.37 nm to about 1 nm. In some embodiments, the dielectric layer 118 is an oxide layer and has a thickness in a range from about 5 nm to about 200 nm.

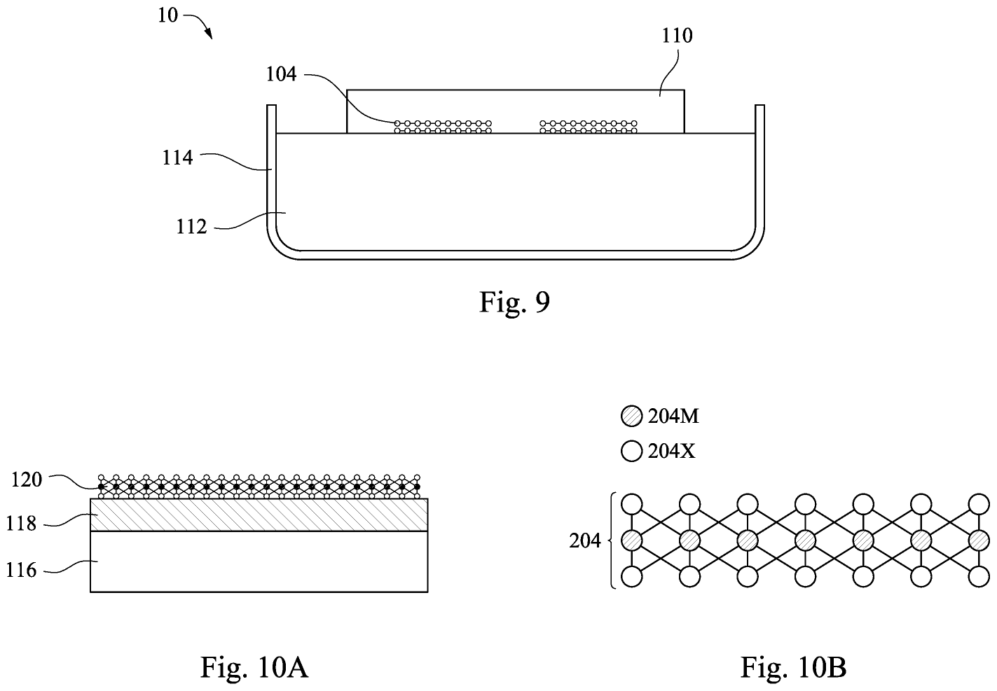

FIG. 14 is a band diagram illustrating an energy barrier between the first 2D material layer 104 and the second 2D material layer 120 of the semiconductor device 10 in FIG. 13. In FIG. 14, Ec denotes a conduction band edge of second 2D material layer 120, Ev denotes a valence band edge of second 2D material layer 120 of, and E_{F} denotes the Fermi level within the first 2D material layer 104. A work function (Φ) may be a minimum thermodynamic work (energy) needed to remove an electron from a solid to a point in a vacuum outside the solid surface. The so-called vacuum level (E₀) represents the minimum energy that an electron needs to possess in order to completely free itself from a metal or semiconductor. As illustrated in FIG. 14, due to the semimetal property of the first 2D material layer 104, the Fermi level E_{F} lies at the point where the valence and conduction bands of the semimetal touch, also known as the Dirac points. In certain embodiments, the first 2D material layer 104 has a work function Φ₁ of about 4.7 eV±0.2 eV, such as about 4.5 eV. Therefore, the work function Φ₁ allows for the Fermi level E_{F} being closer to the conduction band Ec than to the valance band Ev, and thus the resultant device 10 can act as an n-type FET. In particular, electrons will be dominant carriers in the semiconductor device 10. The first 2D material layer 104 is in contact with the second 2D material layer 120 in certain embodiments. By using the first 2D material layer 104 as the source/drain electrodes and the second 2D material layer 120 as the channel layer, a van der Waals attraction exists at an interface between the first and second 2D material layers 104, 120. In other words, the first 2D material layer 104 forms a van der Waals contact with the second 2D material layer 120. Such van der Waals contact is beneficial for resolving the Fermi Level pinning (FLP) in the second 2D material layer 120 at the interface between the second 2D material layer 120 and the first 2D material layer 104.

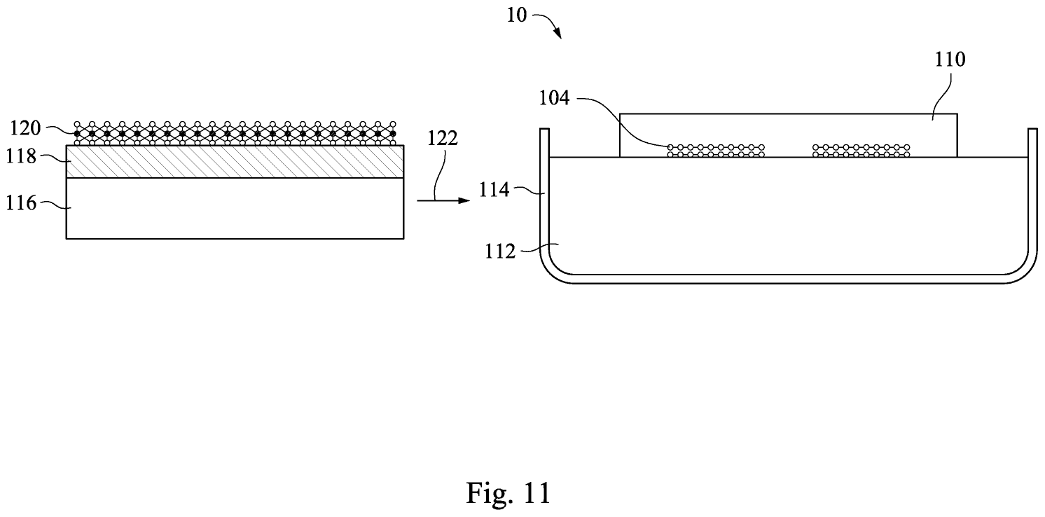

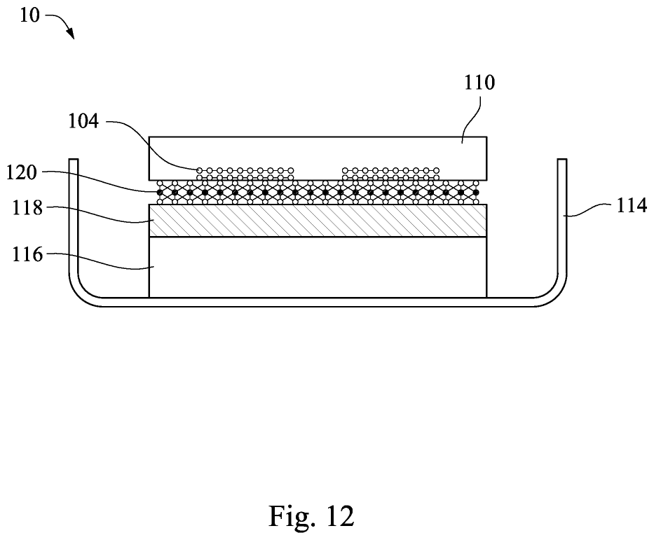

FIGS. 15A, 16A and 17-20 are cross-sectional views of a semiconductor device 12 in various stages of fabrication in accordance with some other embodiments of the present disclosure. FIG. 15A illustrates the resulting structure after the first 2D material layer 104a is patterned. FIG. 15B is a deposition system 30 in accordance with some embodiments of the present disclosure. Reference is made to FIGS. 15A and 15B. The structure is then transferred to a deposition system of FIG. 15. In some embodiments, the deposition system 30 is a furnace. For example, the deposition system 30 includes a processing chamber 300, a gas delivery system 302 and a pumping system 304. In some embodiments, the gas delivery system 302 is connected to the processing chamber 300 via a gas delivery line 306, and the pumping system 304 is connected to the processing chamber 300 via a gas delivery line 308. In some embodiments, the processing chamber 300 is an elongated tube extending laterally. In some embodiments, the gas delivery lines 306, 308 are fluidly connected with the processing chamber 300, in which the gas delivery lines 306, 308 are fluidly communicated with opposite sides of the processing chamber 300. The deposition system 30 includes one or more heaters 310 used as a heating unit (heating mechanism). The heaters 310 have a cylindrical shape and are horizontally installed in a state where the heaters 310 are supported on a heater base (not shown) which is a holding plate. In some embodiments, the processing chamber 300 is a reaction tube constituting a reaction vessel (process vessel) installed concentrically with the heaters 310. The processing chamber 300 is made of a heat-resistant material such as quartz (SiO₂), silicon carbide (SiC) or other suitable materials, and has a cylindrical shape.

At the gas delivery line 306, a flowrate controller (flowrate control unit) such as a mass flow controller (MFC) 312 is connected to a source 314 of the gas delivery system 302 via a valve 316. The valve 316 when opens allows a carrier gas to flow through the gas delivery line 306 and hence selects which precursor(s) would be used for the deposition process. The MFC 312 controls a flow rate of the carrier gas. A valve 317 of the gas delivery line 306 is opened to allow a flow of the carrier gas into the processing chamber 300. The carrier gas may include N₂ gas, a rare gas or an inert gas such as Ar gas, He gas, Ne gas, and Xe gas, or a combination thereof. In some embodiments, the pumping system 304 includes a pressure gauge 318, a foreline trap 320 and a vacuum pump 322. The foreline trap 320 is connected to the gas delivery line 308 via a valve 324. The remainder of a gas mixture exhausted from the processing chamber 300, including reaction products or byproducts, is evacuated from the processing chamber 300 by the vacuum pump 322. In some embodiments, the foreline trap 320 may be a particle collector or a particle filter, which is positioned downstream from an exhaust gas source (e.g., the processing chamber 300).

In some embodiments wherein the first 2D material layer 104a includes graphene, the first 2D material layer 104a becomes a graphite intercalated compound (GIC) formed by an intercalation process conducted in the deposition system 30. Reference is made to FIGS. 15A and 15B. For example, the processing chamber 300 can accommodate the structure of FIG. 15A and an intercalation material 124. In some embodiments, the intercalation material 124 may be metal chloride material in a powder form. For example, the intercalation material 124 may include FeCl₃, MoCl₅, CuCl₂, the like, or a combination thereof. During the intercalation process, in some embodiments, the processing chamber 300 may be heated by the heaters 310 to reach a temperature of about 200° C. to about 360° C., and a processing pressure of the intercalation process may be in a range from about 0.1 torr to about 760 torr. In some embodiments, the intercalation time of the intercalation process is in a range from about 5 minutes to about 120 minutes.

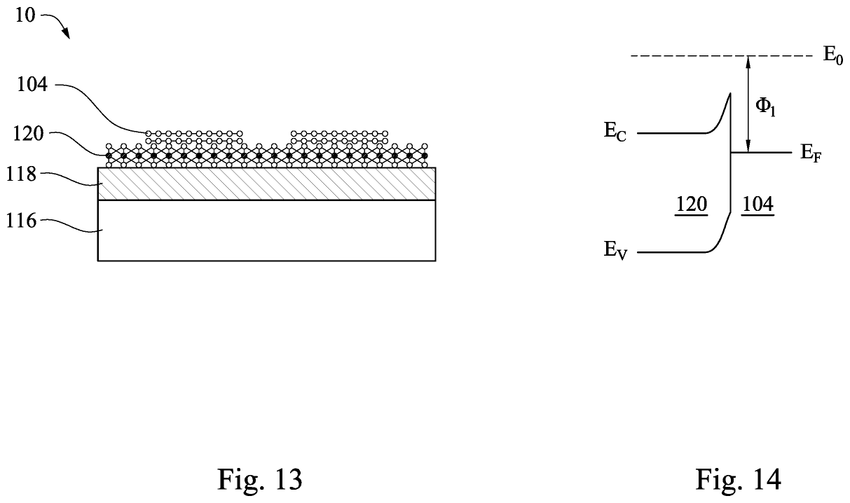

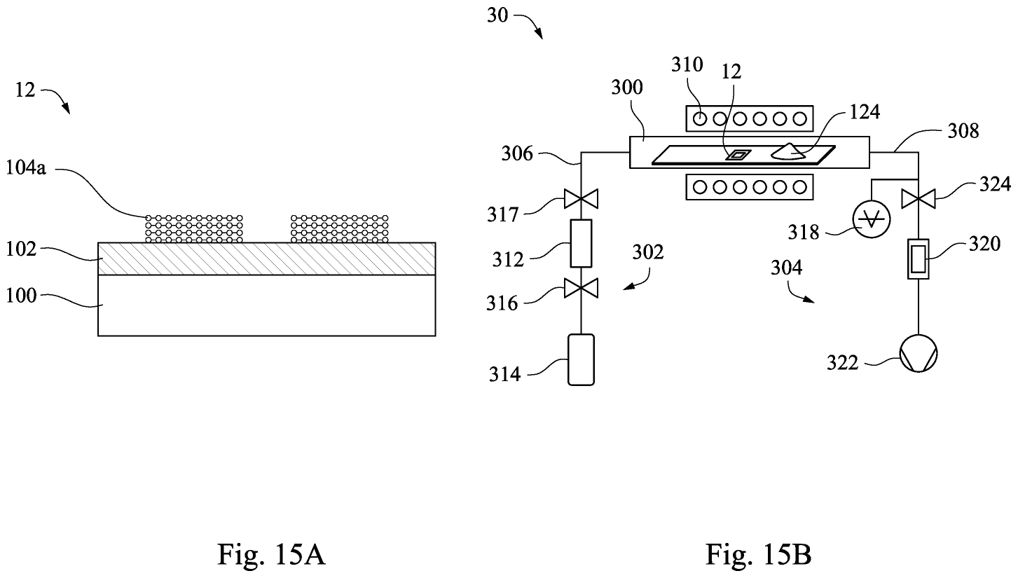

FIG. 16B is an enlarged view of a region R2 in FIG. 16A. A Reference is made to FIGS. 16A and 16B. After the intercalation process, the first 2D material layer 104a has one or more insertion layers (i.e., insertion of atomic or molecular layers) 126 of different materials than carbon between layers of carbons 105 in graphite. In some embodiments, the insertion layers 126 may be made of the materials of the intercalation material 124, for example, FeCl₃, MoCl₅, CuCl₂, the like, or a combination thereof. The insertion layers 126 can be referred to as intercalation layers. The work function of the first 2D material layer 104a can be changed by performing the intercalation process to the first 2D material layer 104a such that the first 2D material layer 104a becomes a graphite intercalated compound (GIC). For example, the work function of the first 2D material layer 104a can be increased, which will be discussed in greater details in subsequent paragraphs. The increased work function is beneficial for fabricating p-type FETs.

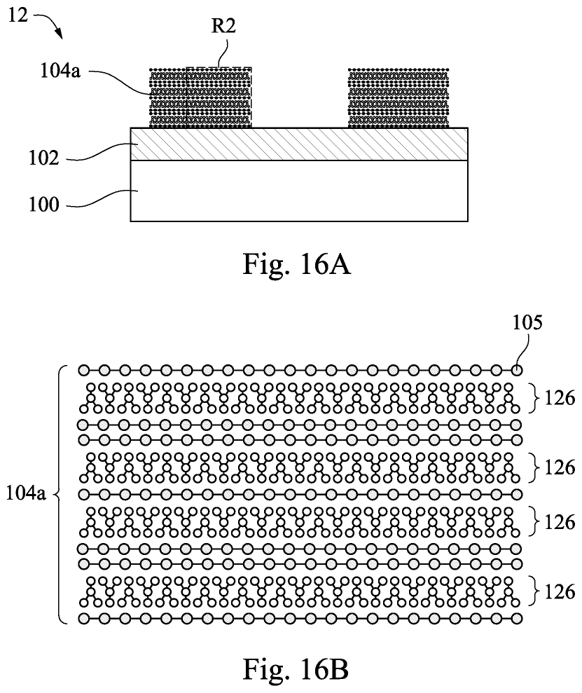

Reference is made to FIG. 17. In some embodiments, an organic film 128 is formed on the first 2D material layer 104a. The organic film 128 is similar to the organic film 110 as discussed previously with regard to FIG. 8 in terms of composition and formation method, and thus the description thereof is omitted herein. In some embodiments, the organic film 128 has a thickness in a range from about 50 nm to about 200 nm.

A substrate removing operation is then performed to the structure in FIG. 17. FIG. 18 depicts the semiconductor device 12 after the substrate removing operation removes the first substrate 100 and the dielectric layer 102. As a result of the substrate removing operation, the organic film is peeled from the dielectric layer 102. Due to strong adhesion between the organic film and the first 2D material layer 104a, the first 2D material layer 104a is also peeled off from the dielectric layer 102 together with the organic film 128. In some embodiments of the substrate removing operation, the structure of FIG. 18 is immersed in the water 112 (i.e., deionized water) such that the first substrate 100 and the dielectric layer 102 are detached from the organic film 128. Ultrasonic vibrations may be applied to the water 112 to promote the detachment of the organic film 128 and the first 2D material layer 104a. In some embodiments, the water 112 is contained in the container 114 made of, for example, glass or other suitable material. Upon detachment is completed, the organic film 128 and the first 2D material layer 104a may float on the water 112, as shown in FIG. 18.

In other embodiments, the organic film 128 is mechanically peeled off from the first substrate 100 together with the first 2D material layer 104a. In other embodiments, the first substrate 100 is wet etched, thereby releasing the organic film 128 with the first 2D material layer 104a. When the first substrate 100 is thick, a grinding operation to remove the bulk portion of the first substrate from the rear side of the first substrate 100 and then a wet etching operation is performed to remove the remaining layer of the first substrate 100.

Next, the structure of FIG. 17 is put in the water 112 contained in the container 114 of FIG. 18. In some embodiments, the second substrate 116 sinks to a bottom of the water 112. Afterwards, the water 112 is removed. As a result of removal of the water, the floated organic film 128 and the first 2D material layer 104a may then land on or be placed on the second 2D material layer 120. The resulting structure is shown in FIG. 19.

The organic film 128 is then removed from the first 2D material layer 104a using a suitable solvent, for example, acetone or the like. The resulting structure is shown in FIG. 20. The semiconductor device 12 constructs a bottom gate field effect transistor (FET). For example, the second substrate 116 may be doped with dopants and act as a bottom electrode, such as a bottom gate. The first 2D material layer 104a is a semimetal material and acts as source/drain electrodes. As discussed previously, the first 2D material layer 104a may be a graphite intercalated compound and has a thickness in a range from about 1 nm to about 150 nm. The second 2D material layer 120 acts as a channel layer. In some embodiments, the second 2D material layer 120 includes TMD and has a thickness in a range from about 0.37 nm to about 1 nm. In some embodiments, the dielectric layer 118 is an oxide layer and has a thickness in a range from about 5 nm to about 200 nm.

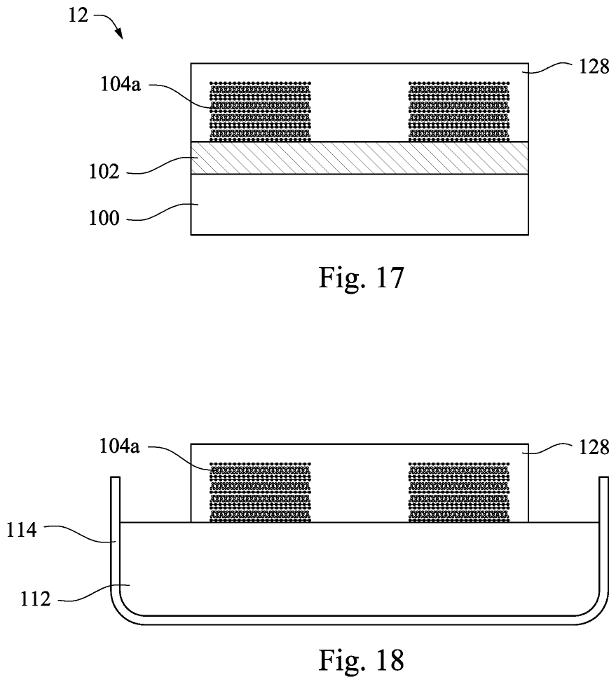

FIG. 21 is a band diagram illustrating an energy barrier between the first 2D material layer 104a and the second 2D material layer 120 of the semiconductor device 12 in FIG. 20. The main difference between the two band diagrams in FIG. 14 and FIG. 21 is that the first 2D material layer 104a has a work function greater than the work function of the first 2D material layer 104 of the semiconductor device 10 in FIG. 13. For example, the first 2D material layer 104a has a work function Φ₂ of about 5.3 eV±0.2 eV, such as about 5.5 eV. Therefore, the work function Φ₂ allows for the Fermi level E_{F} being closer to the valence band of the second 2D material layer 120 than to the valance band Ev of the second 2D material layer, and thus the resultant device 12 can act as a p-type FET. In particular, holes are dominant charge carriers in the semiconductor device 12, which has a different behavior than the semiconductor device 10 described previously with respect to FIGS. 13 and 14.

The first 2D material layer 104a is in contact with the second 2D material layer 120 in certain embodiments. By using the first 2D material layer 104a as the source/drain electrodes and the second 2D material layer 120 as the channel layer, a van der Waals attraction exist at an interface between the first and second 2D material layers 104, 120. In other words, the first 2D material layer 104a forms a van der Waals contact with the second 2D material layer 120. Such van der Waals contact is beneficial for resolving the Fermi Level pinning (FLP) in the second 2D material layer 120 at the interface between the second 2D material layer 120 and the first 2D material layer 104a.

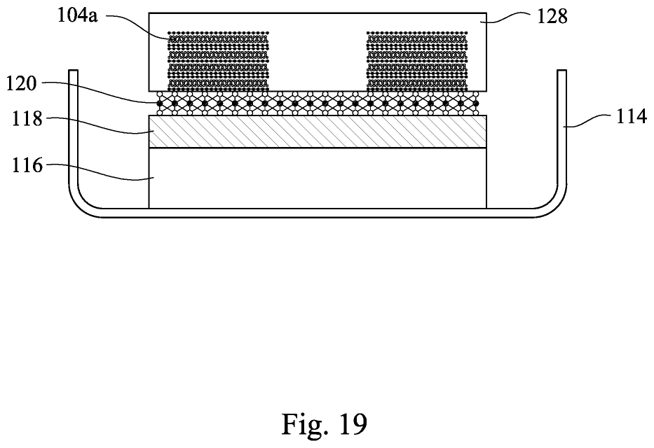

FIG. 22 is a diagram illustrating a current versus voltage (I-V) curve of the semiconductor device 10 of FIG. 13 according to one embodiment. The I-V curve is constructed according to experimental data from one sample of the semiconductor device 10 of FIG. 13. A horizontal axis of the diagram represents a voltage applied to the structure (or a bias voltage applied to the second substrate 116 in one example). The corresponding unit is volt (or V). A vertical axis of the diagram represents a current through the semiconductor device 10. A curve 1000 is on linear scale. A curve 1002 is on a log scale in which the voltage (V) is linear and the current (I) is on a log scale. The I-V curve includes a first voltage range 1004 that is positive or in one polarity and a second voltage range 1006 that is negative or in opposite polarity. Thus, the operations of the semiconductor device 10 can be in a bipolar mode, and the majority charge carriers in the semiconductor device 10 can be electrons or holes, which indicate that the semiconductor device 10 can be used for the n-type FETs or the p-type FETs.

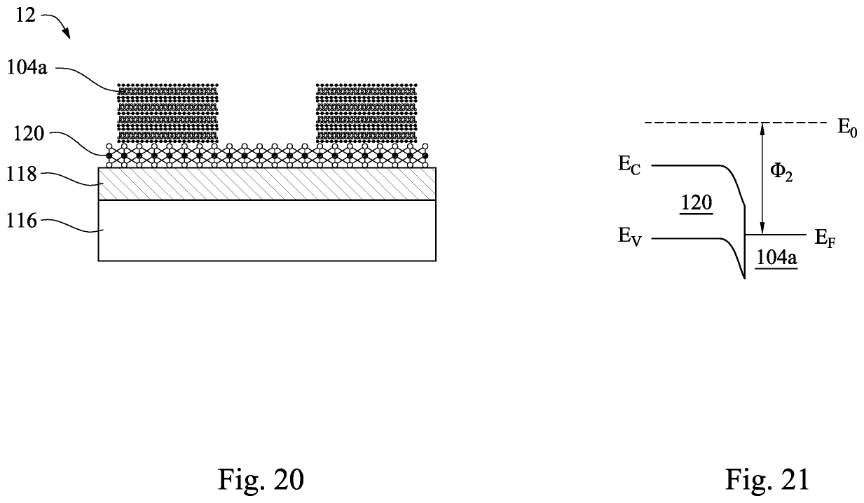

FIG. 23 is a diagram illustrating a current versus voltage (I-V) curve of the semiconductor device 12 of FIG. 20 according to one embodiment. The I-V curve is constructed according to experimental data from one sample of the semiconductor device 12 of FIG. 20. A curve 1008 is on linear scale. A curve 1010 is on a log scale in which the voltage (V) is linear and the current (I) is on a log scale. The I-V curve includes a voltage range 1012 that is negative or in only one polarity and. Thus, the operations of the semiconductor device 12 can be in a unipolar mode, and the majority charge carriers in the semiconductor device 12 are holes, which indicate that the semiconductor device 12 can be used for the p-type FETs.

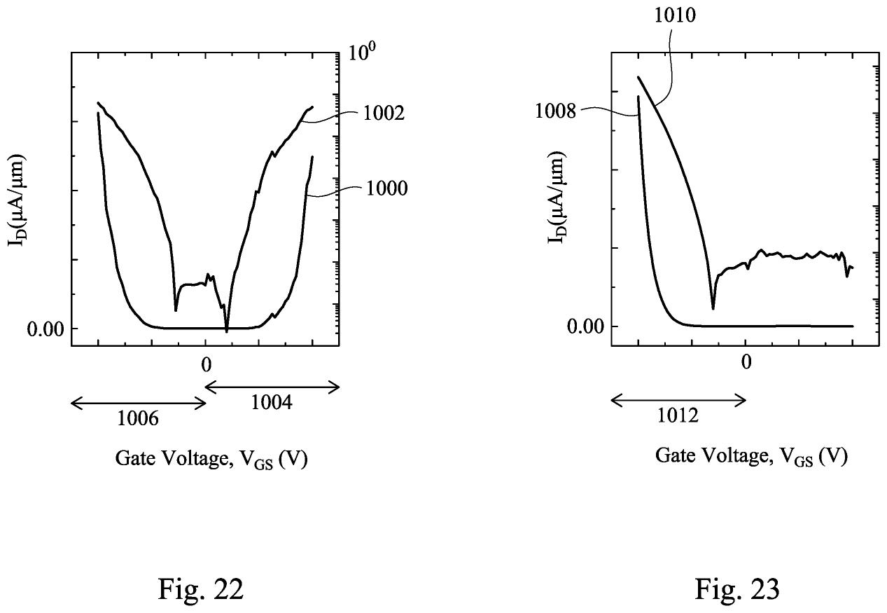

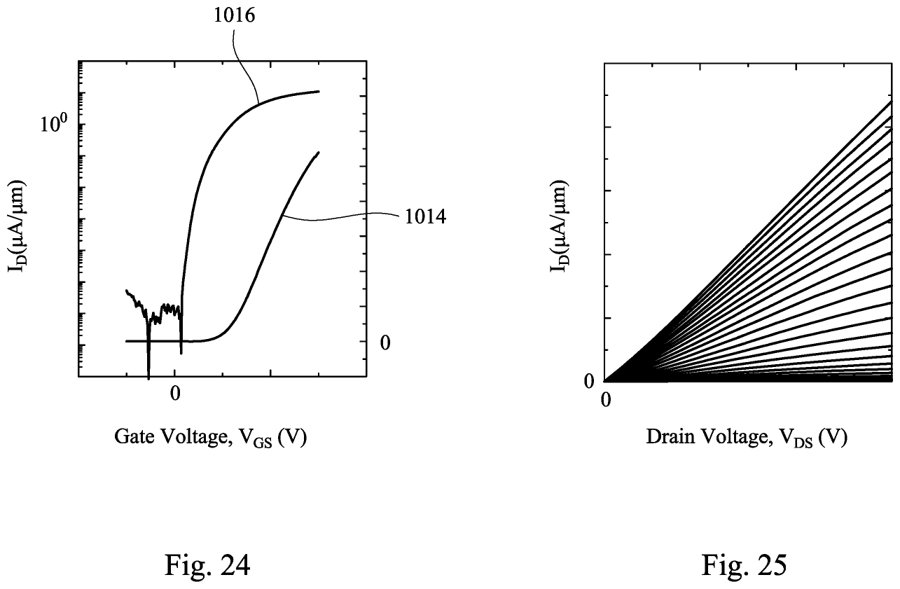

FIG. 24 is a graph of transfer curves for the semiconductor device 10 of FIG. 13 in accordance with some embodiments. A curve 1014 is on a linear scale. A curve 1016 is on a log scale in which the voltage (V) is linear and the current (I) is on a log scale. In FIG. 24, the horizontal axis represents a gate voltage applied to the semiconductor device 10. FIG. 25 is a graph of an output curve for the semiconductor device 10 of FIG. 13 in accordance with some embodiments in dependency on the gate voltage (varying from 0 V to 30 V in about 1±0.1V steps). In FIG. 25, the horizontal axis represents a drain voltage applied to the semiconductor device 10 (or a bias voltage applied to the semiconductor device 10 in one example). The corresponding unit is volt (or V). The vertical axis represents a drain current through the semiconductor device 10. Reference is made to FIGS. 13, 24 and 25. The semiconductor device 10 has a substantially linear I-V curve when the gate voltage is from 0 V to 30 V. In some embodiments when the drain voltage is about 0 V to about 3 V, the straight lines through the origin represent a linear circuit element.

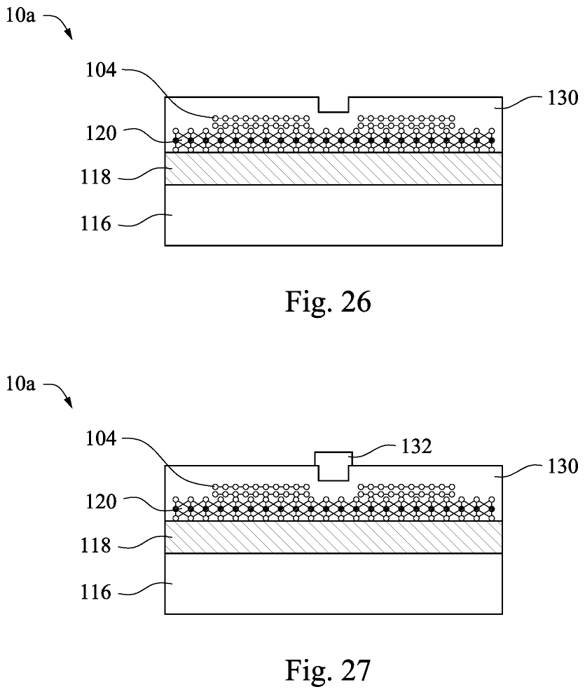

FIGS. 26 and 27 are cross-sectional views of a semiconductor device 10a in various stages of fabrication in accordance with some embodiments of the present disclosure. FIG. 26 illustrates the resulting structure after the first 2D material layer 104 is placed on the second 2D material layer 120. Reference is made to FIG. 26. In some embodiments, a dielectric layer 130 is formed on the second 2D material layer 120. For example, the dielectric layer 130 may be an oxide layer including, for example, SiO₂, Al₂O₃. HfOx, or the like formed using a suitable deposition method, such as ALD, CVD, PVD, or the like. In certain embodiments, the dielectric layer 130 has a thickness in a range from about 5 nm to about 200 nm. The dielectric layer 130 extends over and covers the dielectric layer 118, the second 2D material layer 120 and the first 2D material layer 104.

Reference is made to FIG. 27. A top electrode 132 is formed over the dielectric layer 130. The top electrode 132 may be formed by PVD. CVD, ALD, or other suitable technique. The top electrode may include a conductive material such as a metal. In some embodiments, the top electrode 132 may be aluminum, aluminum alloy, copper, copper alloy, titanium, titanium nitride, tantalum, tantalum nitride, tungsten, the like, and/or combinations thereof. In some embodiments, formation of the top electrode may include forming a top electrode layer over the dielectric layer 130 and forming a hard mask (not shown) covering the top electrode layer. The hard mask may be or comprise, for example, silicon nitride, some other suitable nitride(s), some other suitable dielectric(s), or any combination of the foregoing. Further, the hard mask may be formed by a deposition method, for example, ALD, CVD, PVD, or some other suitable deposition process, and/or be patterned by, for example, using a photolithography/etching process or some other suitable patterning process. The top electrode 132 acts as a top gate electrode, and thus the semiconductor device 10a constructs a top gate field effect transistor (FET).

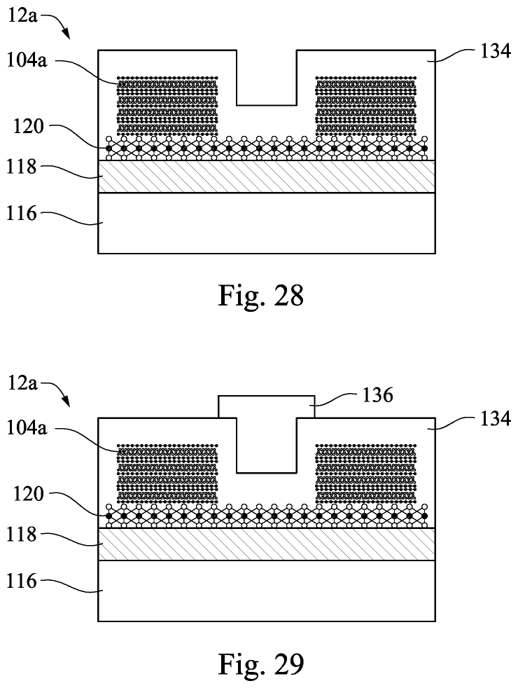

FIGS. 28-29 are cross-sectional views of a semiconductor device in various stages of fabrication in accordance with some embodiments of the present disclosure. FIG. 28 illustrates the resulting structure after the first 2D material layer 104a is placed on the second 2D material layer 120. Reference is made to FIG. 28. In some embodiments, a dielectric layer 134 is formed on the second 2D material layer 120. The dielectric layer 134 is similar to the dielectric layer 130 as discussed previously with regard to FIG. 26 in terms of composition and formation method, and thus the description thereof is omitted herein.

Reference is made to FIG. 29. A top electrode 136 is formed over the dielectric layer 134. The top electrode 136 is similar to the top electrode 132 as discussed previously with regard to FIG. 27 in terms of composition and formation method, and thus the description thereof is omitted herein. The top electrode 136 acts as a top gate electrode, and thus the semiconductor device 12a constructs a top gate field effect transistor (FET).

Based on the above discussions, it can be seen that the present disclosure in various embodiments offers advantages. It is understood, however, that other embodiments may offer additional advantages, and not all advantages are necessarily disclosed herein, and that no particular advantage is required for all embodiments. One advantage is that the work function of the first 2D material layer can be changed by performing an intercalation process to the first 2D material layer such that the n-type FETs and the p-type FETs can be fabricated by controlling the intercalation process. Another advantage is that due to the first 2D material layer forming a van der Waals contact with the second 2D material layer, the Fermi Level pinning (FLP) in the second 2D material layer at the interface between the second 2D material layer and the first 2D material layer can be resolved.

In some embodiments, a semiconductor device comprises a substrate, a first dielectric layer over the substrate, a channel layer over the first dielectric layer, and source/drain electrodes over the channel layer. The source/drain electrodes comprise a 2D semimetal material, and the channel layer comprises a 2D semiconductor material interfacing the 2D semimetal material of the source/drain electrodes. In some embodiments, the 2D semimetal material of the source/drain electrodes includes graphene. In some embodiments, the 2D semimetal material of the source/drain electrodes comprises an intercalation material. In some embodiments, the intercalation material is metal chloride. In some embodiments, the intercalation material is FeCl₃, MoCl₅, CuCl₂, or a combination thereof. In some embodiments, the 2D semimetal material of the source/drain electrodes comprises a graphite intercalated compound. In some embodiments, the semiconductor device further comprises a second dielectric layer over the source/drain electrodes and a top electrode over the second dielectric layer.

In some embodiments, a semiconductor device includes a semiconductor substrate, a dielectric layer over the semiconductor substrate, a semiconductor layer over the dielectric layer, and a graphene-containing layer over the semiconductor layer. The graphene-containing layer has separated portions spaced apart along a lateral dimension. In some embodiments, the semiconductor layer includes transition metal dichalcogenide (TMD). In some embodiments, the graphene-containing layer is a semimetal having a Fermi level closer to a conduction band edge of the TMD than to a valance band edge of the TMD. In some embodiments, the graphene-containing layer is a semimetal having a Fermi level closer to a valance band edge of the TMD than to a conduction band edge of the TMD.

In some embodiments, a method of forming a semiconductor device includes the following steps. A first 2D material layer is formed over a first substrate. The first 2D material layer has a first work function. The first 2D material layer is patterned. The first substrate is removed. A dielectric layer is formed over a second substrate. A second 2D material layer is formed over the dielectric layer. The first 2D material layer is disposed over the second 2D material layer. In some embodiments, the method further comprises after patterning the first 2D material layer, performing an intercalation process to the first 2D material layer. In some embodiments, performing the intercalation process comprises intercalating the first 2D material layer using a metal chloride. In some embodiments, performing the intercalation process comprises accommodating the first 2D material layer over the first substrate in a chamber, accommodating a metal chloride material in the chamber, introducing a gas into the chamber and heating the chamber. In some embodiments, after performing the intercalation process, the first 2D material layer has a second work function different from the first work function. In some embodiments, the second work function is greater than the first work function. In some embodiments, the method further comprises the following steps. After patterning the first 2D material layer, an organic film is formed over the first 2D material layer. After disposing the first 2D material layer over the second 2D material layer, the organic film is removed. In some embodiments, the first 2D material layer is graphite intercalated compound. In some embodiments, the first 2D material layer is graphene.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a substrate;
a first dielectric layer over the substrate;
a channel layer over the first dielectric layer; and
source/drain electrodes over the channel layer, wherein the source/drain electrodes comprise a 2D semimetal material, and the channel layer comprises a 2D semiconductor material interfacing the 2D semimetal material of the source/drain electrodes.

2. The semiconductor device of claim 1, wherein the 2D semimetal material of the source/drain electrodes includes graphene.

3. The semiconductor device of claim 1, wherein the 2D semimetal material of the source/drain electrodes comprises an intercalation material.

4. The semiconductor device of claim 3, wherein the intercalation material is metal chloride.

5. The semiconductor device of claim 3, wherein the intercalation material is FeCl₃, MoCl₅, CuCl₂, or a combination thereof.

6. The semiconductor device of claim 1, wherein the 2D semimetal material of the source/drain electrodes comprises a graphite intercalated compound.

7. The semiconductor device of claim 1, further comprising:
a second dielectric layer over the source/drain electrodes; and
a top electrode over the second dielectric layer.

8. A semiconductor device, comprising:
a semiconductor substrate;
a dielectric layer over the semiconductor substrate;
a semiconductor layer over the dielectric layer; and
a graphene-containing layer over the semiconductor layer, wherein the graphene-containing layer has separated portions spaced apart along a lateral dimension.

9. The semiconductor device of claim 8, wherein the semiconductor layer includes transition metal dichalcogenide (TMD).

10. The semiconductor device of claim 9, wherein the graphene-containing layer is a semimetal having a Fermi level closer to a conduction band edge of the TMD than to a valance band edge of the TMD.

11. The semiconductor device of claim 9, wherein the graphene-containing layer is a semimetal having a Fermi level closer to a valance band edge of the TMD than to a conduction band edge of the TMD.

12. A method of forming a semiconductor device, comprising:
forming a first 2D material layer over a first substrate, wherein the first 2D material layer has a first work function;
patterning the first 2D material layer;
removing the first substrate;
forming a dielectric layer over a second substrate;
forming a second 2D material layer over the dielectric layer; and
disposing the first 2D material layer over the second 2D material layer.

13. The method of claim 12, further comprising:
after patterning the first 2D material layer, performing an intercalation process to the first 2D material layer.

14. The method of claim 13, wherein performing the intercalation process comprises:
intercalating the first 2D material layer using a metal chloride.

15. The method of claim 13, wherein performing the intercalation process comprises:
accommodating the first 2D material layer over the first substrate in a chamber;
accommodating a metal chloride material in the chamber;
introducing a gas into the chamber; and
heating the chamber.

16. The method of claim 13, wherein after performing the intercalation process, the first 2D material layer has a second work function different from the first work function.

17. The method of claim 16, wherein the second work function is greater than the first work function.

18. The method of claim 16, further comprising:
after patterning the first 2D material layer, forming an organic film over the first 2D material layer; and
after disposing the first 2D material layer over the second 2D material layer, removing the organic film.

19. The method of claim 12, wherein the first 2D material layer is graphite intercalated compound.

20. The method of claim 12, wherein the first 2D material layer is graphene.
